(19) United States
(12) Patent Application Publication
(10) Pub. No.: US 2025/0355145 A1
(43) Pub. Date: Nov. 20, 2025

(54) METHOD FOR OPTIMIZING MASK ABSORPTION MATERIAL BASED ON SURFACE PLASMON MULTILAYER STRUCTURE, AND PLASMONIC SUPERLENS

(71) Applicant: INSTITUTE OF MICROELECTRONICS, CHINESE ACADEMY OF SCIENCES, Beijing (CN)

(72) Inventors: Jianfang He, Beijing (CN); Yayi Wei; Huwen Ding, Beijing (CN)

(21) Appl. No.: 18/709,587

(22) PCT Filed: Dec. 28, 2023
(86) PCT No.: PCT/CN2023/142635

§ 371 Date: May 13, 2024

(30) Foreign Application Priority Data
Dec. 25, 2023 (CN) 202311797320.X

(51) Int. Cl. G02B 5/00; G03F 7/00

(52) U.S. Cl. CPC G02B 5/008; G03F 7/70504

(57) ABSTRACT

A method for optimizing a mask absorption material based on a surface plasmon multilayer structure. The method comprises: S1) constructing a plurality of structures for a multilayer superlens; S2) simulating light transmission in each structure of the plurality of structures through software modelling to obtain an image contrast of a pattern formed at a central region of a photoresist coated on a base layer; and S3) determining the parameter of the layer of the plurality of absorption masks for a structure of the multilayer superlens based on the image contrast. In comparison with the conventional technology, the above method is based on the multilayer structure and optimizes three-dimensional parameters of the absorption mask(s). Experiments have shown that the above method has a significant effect on improving the resolution and the image contrast of the multilayer structure.

This application claims priority to Chinese Patent Application No. 202311797320.X, titled “METHOD FOR OPTIMIZING MASK ABSORPTION MATERIAL BASED ON SURFACE PLASMON MULTILAYER STRUCTURE, AND PLASMONIC SUPERLENS”, filed on Dec. 25, 2023 with the Chinese Patent Office, which is incorporated herein by reference in its entirety.

### FIELD

The present disclosure relates to the technical field of semiconductors, and in particular to a method for optimizing a mask absorption material based on a surface plasmon multilayer structure, and a plasmonic superlens.

### BACKGROUND

Surface plasmons are capable to carry evanescent waves through specifically designed metal-dielectric coupling between thin films, and thereby achieve imaging of a fine structure of an object having a feature size much smaller than magnitude of a wavelength. Hence, the surface plasmons provide a feasible approach for breaking through the diffraction limit and manipulating a light field.

At beginning of the 21^{st} century, J. B. Pendry of the Britain proposed the concept of a “superlens” capable to achieve sub-diffraction imaging. Due to a negative refractive index in optics, the superlens is capable to transmit evanescent waves in a high frequency band through coupling, and thereby achieves the sub-diffraction imaging. In recent years, extensive researches and progresses have been witnessed in the field of the sub-diffraction imaging for breaking through optical limits and improving an imaging resolution.

A lot of researches have been carried out on lenses of sub-diffraction imaging systems, that is, on multilayer films. Structural parameters of the sub-diffraction lenses have been improved and optimized for higher imaging resolution and higher imaging contrast. Currently, there is scarcely any research on optimization of parameters of a mask, which is closely related to an imaging structure.

### SUMMARY

At least in view of the above, a technical issue addressed in embodiments of the present invention is providing a method for optimizing a mask absorption material based on a surface plasmon multilayer structure and providing a plasmonic superlens. Resolution and an image contrast are enhanced for photolithography using the plasmonic superlens.

A method for optimizing a mask absorption material based on a surface plasmon multilayer structure is provided according to an embodiment of the present disclosure. The method comprises: S1) constructing a plurality of structures for a multilayer superlens, where: each structure of the plurality of structures comprises quartz glass, a layer of a plurality of absorption masks, a polymer spacer layer, and a multilayer structure comprising at least one metallic layer and at least one dielectric layer which are alternately stacked: the layer of the plurality of absorption masks is disposed on a surface of the quartz glass: the polymer spacer layer is disposed among the plurality of absorption masks and on a surface of the layer of the plurality of absorption masks: the multilayer structure is disposed on a surface of the polymer spacer layer; and structures in the plurality of structures differ from each other in a parameter of the layer of the plurality of absorption masks: S2) simulating light transmission in each structure of the plurality of structures through software modelling to obtain an image contrast of a pattern formed at a central region of a photoresist coated on a base layer; and S3) determining the parameter of the layer of the plurality of absorption masks for a structure of the multilayer superlens based on the image contrast.

In an embodiment, the parameter of the layer of the plurality of absorption masks comprises at least one of: a thickness of the layer of the plurality of absorption masks, a type of a material of the layer of the plurality of absorption masks, or an angle of a sidewall of each absorption mask in the plurality of absorption masks.

In an embodiment, the thickness of the layer of the plurality of absorption masks ranges from 10 nm to 160 nm, each absorption mask of the plurality of absorption masks comprises one or both of a MoSi layer and a Cr layer, the MoSi layer is in contact with the quartz glass when said absorption mask comprises both the MoSi layer and the Cr layer, and the angle of the sidewall of each absorption mask ranges 0° to 30°.

In an embodiment, the plurality of structures comprises structures, the layer of the plurality of absorption masks of each of which comprises the Cr layer and which differ from each other in a thickness of the Cr layer, and other structures, the layer of the plurality of absorption masks of each of which comprises the MoSi layer and the Cr layer and which differ from each other in a thickness of the MoSi layer and are identical in the thickness of the Cr layer, where the MoSi layer is in contact with the quartz glass.

In an embodiment, the plurality of structures comprises structures which differ from each other in the angle of the sidewall of each absorption mask.

In an embodiment, a width of a gap between adjacent absorption masks in the plurality of absorption masks ranges from 140 nm to 160 nm, and a periodical dimension of the plurality of absorption masks ranges from 280 nm to 320 nm.

In an embodiment, a thickness of the polymer spacer layer ranges from 100 nm to 200 nm, and a thickness of the multilayer structure ranges from 250 nm to 350 nm.

In an embodiment, the polymer spacer layer comprises a PMMA layer, the multilayer structure comprises at least one silver layer and at least one titanium dioxide layer which are alternately stacked, and one of the at least one titanium dioxide layer is a layer closest to the polymer spacer layer in the multilayer structure.

In an embodiment, simulating the light transmission in each structure of the plurality of structures through the software modelling comprises: altering an incident angle of light from a light source to obtain the image contrast, where the incident angle ranges from 0° to 20°.

A plasmonic superlens is further provided according to an embodiment of the present disclosure. The plasmonic superlens is fabricated through the foregoing method.

Herein the method for optimizing the mask absorption material based on the surface plasmon multilayer structure is provided according to embodiments of the present disclosure. The method comprises: S1) constructing the plurality of structures for the multilayer superlens, where: each structure of the plurality of structures comprises the quartz glass, the layer of the plurality of absorption masks, the polymer spacer layer, and the multilayer structure comprising the at least one metallic layer and the at least one dielectric layer which are alternately stacked: the layer of the plurality of absorption masks is disposed on the surface of the quartz glass: the polymer spacer layer is disposed among the plurality of absorption masks and on the surface of the layer of the plurality of absorption masks: the multilayer structure is disposed on the surface of the polymer spacer layer; and the structures in the plurality of structures differ from each other in the parameter of the layer of the plurality of absorption masks: S2) simulating the light transmission in each structure of the plurality of structures through the software modelling to obtain the image contrast of the pattern formed at the central region of the photoresist coated on the base layer; and S3) determining the parameter of the layer of the plurality of absorption masks for the structure of the multilayer superlens based on the image contrast. In comparison with the conventional technology, the above method is based on the multilayer structure and optimizes three-dimensional parameters of the absorption mask(s). Experiments have shown that the above method has a significant effect on improving the resolution and the image contrast of the multilayer structure.

### BRIEF DESCRIPTION OF THE DRAWINGS

FIG. 1 is a schematic structural diagram of imaging through a multilayer superlens structure according to an embodiment of the present disclosure.

FIG. 2 is a schematic structural diagram of a parameter of a layer of absorption masks according to an embodiment of the present disclosure.

FIG. 3 is a schematic structural diagram of a structure for a multilayer superlens in which each absorption mask comprises a MoSi layer and a Cr layer according to an embodiment of the present disclosure.

FIG. 4 is a graph of image contrasts of a pattern with respect to an incident angle of light from a light source for layers of absorption masks made of Cr and OMOG, respectively, both of which have a thickness of 60 nm and a sidewall angle of 0°, according to an embodiment of the present disclosure.

FIG. 5 is a graph of image contrasts of a pattern with respect to a thickness for layers of absorption masks made of Cr and OMOG, respectively, both of which have a sidewall angle of 0° and are subject to vertical incident light, according to an embodiment of the present disclosure.

FIG. 6 is a graph of image contrasts of a pattern with respect to a sidewall angle for layers of absorption masks made of Cr and OMOG, respectively, both of which have a thickness of 60 nm and are subject to vertical incident light, according to an embodiment of the present disclosure.

### DETAILED DESCRIPTION OF EMBODIMENTS

Hereinafter technical solutions in embodiments of the present disclosure are described clearly and completely in conjunction with the drawings in embodiments of the present closure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

A method for optimizing a mask absorption material based on a surface plasmon multilayer structure is provided according to an embodiment of the present disclosure. The method comprises steps S1 to S3. In step S1, multiple structures are construed for a multilayer superlens. Each structure comprises quartz glass, a layer of multiple absorption masks, a polymer spacer layer, and a multilayer structure comprising at least one metallic layer and at least one dielectric layer which are alternately stacked. The layer of the multiple absorption masks is disposed on a surface of the quartz glass. The polymer spacer layer is disposed among the multiple absorption masks and on a surface of the layer of the multiple absorption masks. The multilayer structure is disposed on a surface of the polymer spacer layer. The multiple structures differ from each other in a parameter of the layer of the multiple absorption masks. In step S2, light transmission in each structure for the multilayer superlens is simulated through software modelling, so as to obtain an image contrast of a pattern formed at a central region of a photoresist which is coated on a base layer. In step S3, the parameter of the layer of the multiple absorption masks is determined for a structure of the multilayer superlens based on the image contrast.

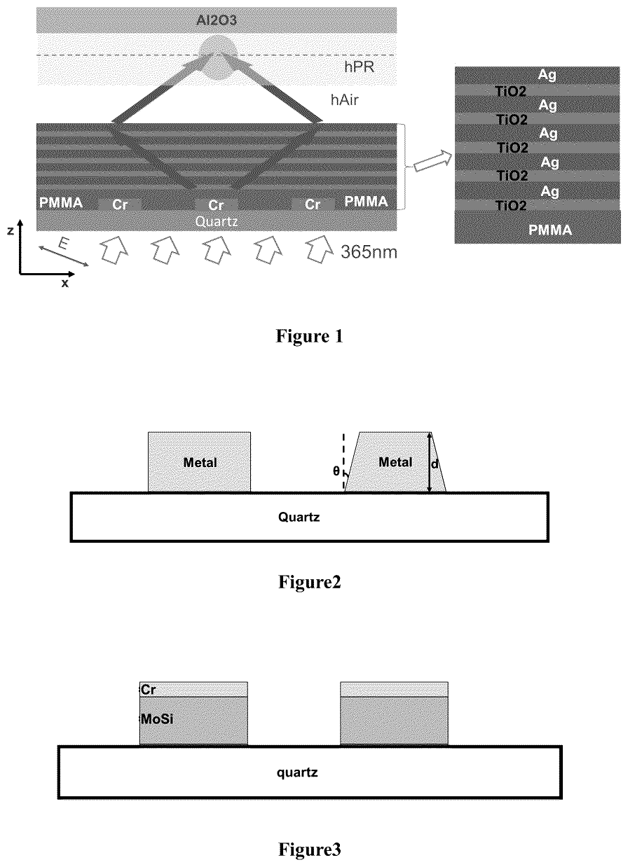

Reference is made to FIG. 1, which is a schematic structural diagram of imaging through a multilayer superlens structure.

Herein a source of raw materials is not specifically limited, and all raw materials may be commercially available.

Multiple structures are construed for a multilayer superlens. Each structure comprises quartz glass, a layer of multiple absorption masks, a polymer spacer layer, and a multilayer structure comprising at least one metallic layer and at least one dielectric layer which are alternately stacked. The multiple structures differ from each other in a parameter of the layer of the absorption masks. The layer of the absorption masks is disposed on a surface of the quartz glass. In an embodiment, a width of a gap between adjacent absorption masks ranges from 140 nm to 160 nm, and is preferably 150 nm. In an embodiment, a periodical dimension of the absorption masks ranges from 280 nm to 320 nm, and is preferably 300 nm. In an embodiment, a thickness of the layer of absorption masks is ranges from 10 nm to 160 nm. In an embodiment, each absorption mask comprises a MoSi layer and/or Cr layer, and the MoSi layer is in contact with the quartz glass when said absorption mask comprises both the MoSi layer and the Cr layer. In an embodiment, an angle of a sidewall, that is, an angle between the sidewall and a vertical direction, of each absorption mask ranges from 0° to 30°. The polymer spacer layer is disposed among the absorption masks and on a surface of the layer of absorption masks. The polymer spacer layer may be made of a polymer well known to those skilled in the art and is not specially limited herein. In an embodiment, the polymer spacer layer is a polymethyl-methacrylate (PMMA) layer. In an embodiment, a thickness of the polymer spacer layer ranges from 100 nm to 200 nm. Such thickness may preferably range from 130 nm to 180 nm, and may more preferably range from 150 nm to 180 nm. The multilayer structure comprising the at least one metallic layer and the at least one dielectric layer which are alternately stacked is disposed on the surface of the polymer spacer layer. The at least one metallic layer and the at least one dielectric layer in the multilayer structure made be made of materials well known to those skilled in the art. In an embodiment, the multilayer structure comprises at least one silver layer and at least one titanium dioxide layer that are alternately stacked, and a layer closet to the polymer spacer in the multilayer structure is one of the at least one titanium dioxide layer. In an embodiment, a quantity of stacking periods in the multilayer structure ranges from 3 to 8. Such quantity may preferably ranges from 4 to 6, and may more preferably be equal to 5. In an embodiment, a thickness of the multilayer structure ranges from 250 nm to 350 nm. Such thickness may preferably range from 280 nm to 320 nm, and may more preferably be equal to 300 nm. Herein the multiple structures for the multilayer superlens differ in the parameter of the layer of the absorption masks, and may be constructed through simulation software. In an embodiment, the parameter of the layer of absorption masks comprises one or more of: the thickness of the layer of the absorption masks, a type of a material of the layer of the absorption masks, and the angle of the sidewall of each of absorption mask. Such parameter may be preferable one of the thickness, the type of the material, and the angle of the sidewall. Reference is made to FIG. 2, which is a schematic structural diagram of the parameter of the layer of the absorption masks. In an embodiment, the multiple structures for the multilayer superlens are identical except for the designated parameter of the layer of absorption masks.

Light transmission in each structure is simulated through software modelling, so as to obtain an image contrast of a pattern formed at a central region of a photoresist coated on a base layer. In an embodiment, the light transmission in each structure for the multilayer superlens structure is simulated through finite-difference time-domain (FDTD) solutions in the software modeling. In an embodiment, a wavelength of a light source for simulating the light transmission in the software modeling ranges from 300 nm to 400 nm. Such wavelength may preferably ranges from 320 nm to 380 nm, may more preferably range from 350 nm to 380 nm, and may most preferably be equal to 365 nm. In an embodiment, incident light from the light source is TM-polarized. In an embodiment, an incident angle of the incident light from the light source ranges from 0° to 20°. Herein the image contrast of the spatial pattern formed in the central region of the photoresist as a means of evaluation. The contrast refers to a ratio of a highest point and a lowest point of the photoresist after exposure and development. In the simulation, the image contrast is generally determined as a ratio of a difference between maximum and minimum light intensity on a photoresist layer to a sum of the maximum and minimum light intensity on the photoresist layer, and such image contrast is also called the Michelson contrast. Greater image contrast indicates that higher steepness of the pattern formed through photolithography, that is, better resolution of photolithography. Generally, the image contrast of a submicron pattern is required to be greater than 0.4 in case of a positive photoresist and greater than 0.2 in case of a negative photoresist. That is, there is a following equation when C represents the image contrast, Iₘₐₓ represents the maximum light intensity, and Iₘᵢₙ represents the minimum light intensity.

$$C = ( {I}_{max} - {I}_{min} ) / ( {I}_{max} + {I}_{min} )$$

The parameter of the layer of the absorption masks of a structure for the multilayer superlens structure may be determined based on the image contrast.

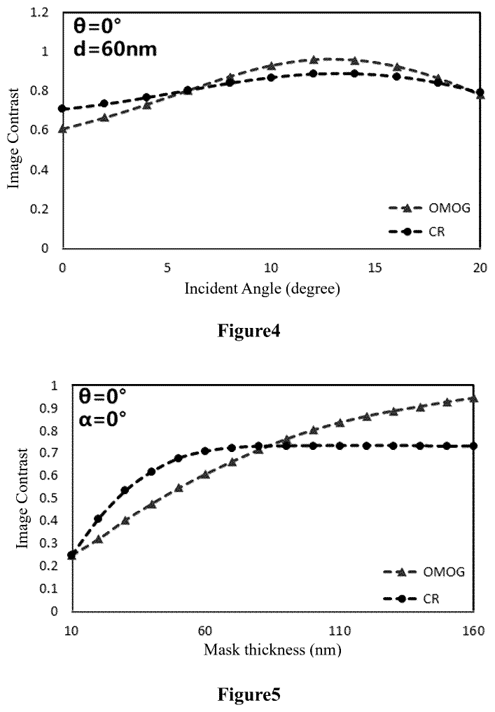

In an embodiment, the multiple structures for the multilayer superlens comprises structures, each absorption mask of which comprises the Cr layer and which differ in a thicknesses of the Cr layer, and other structures, each absorption mask of which comprises comprise the Cr layer and the MoSi layer. Reference is made to FIG. 3, which is a schematic structural diagram of a multilayer superlens in which each absorption masks comprises the MoSi layer and the Cr layer. Among the other structures, a thickness of the Cr layer is identical while a thickness of the MoSi layer is different from each other, and the MoSi layer is in contact with the quartz glass. The light transmission in each structure for the multilayer superlens is simulated through the software modeling to obtain electric field intensity and the image contrast of the spatial pattern formed in the central region of the photoresist coated on the base layer. The parameter of the layer of the absorption masks is determined for the structure for the multilayer superlens based on the electric field intensity and the image contrast. A manner of simulating the light transmission in each structure for the multilayer superlens through software modeling may refer to the one in the foregoing embodiment(s), and would not be repeated herein. In an embodiment, when simulating the light transmission in each structure for the multilayer superlens through software modeling, the wavelength of the light source is configured to be 365 nm, the incident light from the light source is TM-polarized light, and the incident angle of the incident light source is 0°. Thereby, the imaging contrast may be optimized through varying a material of the absorption masks under different mask thicknesses.

Moreover, when the multiple structures for the multilayer superlens comprises the aforementioned structures and the other structures, the multiple structures may be identical in other parameters of the absorption masks. In an embodiment, the sidewall angle of each absorption mask (e.g., the angle between the sidewall and the vertical direction in a case that a cross section of each absorption mask is a trapezoid of which a bottom edge is longer than a top edge) is 0.

Moreover, when the multiple structures for the multilayer superlens comprises the aforementioned structures and the other structures, the thicknesses of the Cr layers in the structures increase stepwise within a range from 10 nm to 160 nm. In an embodiment, a step size of the increase ranges from 5 nm to 20 nm. Such step size may preferably range from 5 nm to 15 nm, and may more preferably be 10 nm. In the other structures, the thickness of Cr layer is identical, while the thicknesses of the MoSi layers are different. In an embodiment, the thickness of the Cr layer may range from 5 nm to 20 nm. Such thickness may preferably range from 5 nm 15 nm, and may more preferably be equal to 10 nm. In an embodiment, the thicknesses of the MoSi layers increase stepwise within a range of 0 to 150 nm. In an embodiment, a step size of the increase ranges from 5 nm to 20 nm. Such step size may preferably range from 5 nm to 15 nm, and may more preferably be 10 nm.

In another embodiment, the multiple structures for the multilayer superlens comprise structures among which the sidewall angle of each absorption mask is different from each other. The light transmission in each structure for the multilayer superlens is simulated through the software modeling to obtain electric field intensity and the image contrast of the spatial pattern formed in the central region of the photoresist coated on the base layer. The parameter of the layer of the absorption masks is determined for the structure for the multilayer superlens based on the electric field intensity and the image contrast. A manner of simulating the light transmission in each structure for the multilayer superlens through software modeling may refer to the one in the foregoing embodiment(s), and would not be repeated herein. In an embodiment, when simulating the light transmission in each structure for the multilayer superlens through software modeling, the wavelength of the light source is configured to be 365 nm, the incident light from the light source is TM-polarized light, and the incident angle of the incident light source is 0°. Thereby, the imaging contrast may be optimized through selecting a material of the absorption masks based on different processing conditions.

Moreover, the aforementioned structures having different sidewall angles are identical in other parameters of the layer of the absorption masks. In an embodiment, each absorption mask may comprise the MoSi layer and/or the Cr layer, and the MoSi layer is in contact with the quartz glass in a case that both exist. In an embodiment, there are both the MoSi layer and the Cr layer, and a ratio of a thickness of the MoSi layer to a thickness of the Cr layer ranges from 3:1 to 6:1. Such ratio may preferably range from 4:1 to 6:1, and may more preferably be equal to 5:1. In an embodiment, the thickness of the layer of absorption masks ranges from 10 nm to 160 nm. The thickness of the layer of absorption masks may be any value within the above range and is not specifically limited herein. Hereinafter the thickness of 60 nm is taken as an example for illustration.

The sidewall angles of the structures for the multilayer superlens may increase stepwise within a range from 0° to 30°. In an embodiment, a step size of the increase may be range from 1° to 10°. Such step size may preferably range from 2° to 8°, may more preferably range from 4° to 6°, and may most preferably be equal to 8°.

In another embodiment, when simulating the light transmission in each structure for the multilayer superlens through the software modeling, an incident angle of light from the light source ranges from 0° to 20°. The light transmission in each structure for the multilayer superlens is simulated through altering the incident angle in the software modeling to obtain electric field intensity and the image contrast of the spatial pattern formed in the central region of the photoresist coated on the base layer. Through this optimization method, different mask absorption materials can be selected according to different process conditions, so as to obtain better imaging contrast.

In an embodiment, the multiple structures for the multilayer superlens differ from each other in the type of the material of the layer of the absorption masks while are identical in other parameters of the layer of the absorption masks. In an embodiment, the layer of the absorption masks comprises the MoSi layer and/or the Cr layer, and the MoSi layer is in contact with the quartz glass in a case that both exist. In an embodiment, there are both the MoSi layer and Cr layer, and a ratio of a thickness of the MoSi layer to a thickness of the Cr layer may range from 3:1 to 6:1. Such ratio may more preferably be equal to 5:1. In an embodiment, the thickness of the layer of absorption masks range from 10 nm to 160 nm. The thickness of the layer of absorption masks may be any value within such range and is not specifically limited herein. Hereinafter the thickness of 60 nm is taken as an example for illustration. The sidewall angle of the layer of the absorption masks may be equal to 0.

In an embodiment, the incident angle of the light source may increase stepwise among the structures. A step size of the increase may range from 1° to 5°. Such step size may preferably range from 2° to 4°, and may more preferably range from 2° to 3°.

Herein the above embodiments may be combined for further optimization. For example, the thickness of the layer of the absorption masks may be optimized according to the incident angle of the light from the light source and the material of the layer of absorption masks.

Embodiments of the present disclosure are based on the multilayer structure and optimize three-dimensional parameters of the absorption mask(s). Experiments have shown that the above solution has a significant effect on improving the resolution and the image contrast of the multilayer structure.

A plasmonic superlens is further provided according to an embodiment of the present disclosure. The plasmonic superlens is fabricated through any foregoing method for optimizing the mask absorption material based on the surface plasmon multilayer structure.

Hereinafter the method for optimizing the mask absorption material based on the surface plasmon multilayer structure and the plasmonic superlens are further illustrated in detail in conjunction with embodiments.

Reagents used hereinafter are all commercially available.

### First Embodiment

In this embodiment, the structure comprising the multilayer structure as shown in FIG. 1 is taken as an example, and the light source is configured to excite surface plasmons of deep sub-wavelength for optimization. The method herein is also applicable to optimization of other similar structures.

The multilayer superlens is configured as follows. The TM-polarized incident light of a wavelength of 365 nm illuminates a surface of the masks with a non-zero incident angle α. The layer of absorption masks is made of Cr on the quartz glass. The width of the gap between adjacent absorption masks is 150 nm, and a periodical dimension of the absorption masks is 300 nm. The superlens comprises five periods of Ag/TiO₂ composite films (where a thickness is 300 nm in total). During fabrication, a layer of PMMA material is applied to planarize the layer of masks. The PMMA layer has a thickness of 150 nm and match a real part of a dielectric constant of the Ag film. Structure details of the masks for simulation may refer to FIG. 2. The thickness of the layer of the absorption masks is equal to d nanometers, and the sidewall angle is equal to θ. The thickness of the photoresist is 50 nm. All components in the y direction is determines to be infinite in simulation.

On a basis of the above structure, a material of the layer of the absorption masks is optimized under an objective of improving the image contrast of the spatial pattern formed in the central region of the photoresist (that is, the image contrast of the spatial pattern formed in the central region of the photoresist serves as an index of evaluation).

The light transmission in each structure is simulated through FDTD solutions in the software modeling, and the electric field intensity and the image contrast of the spatial pattern formed in the central region of the photoresist are calculated for and evaluating an effect of optimization.

In this embodiment, the material of the layer of absorption masks is optimized. Cr (chromium) layer with a thickness of d nanometers may be used. Alternatively, the opaque MoSi on glass (OMOG) may be used as shown in FIG. 3. The OMOG masks is configured as the Cr layer of 10 nm and the MoSi layer of (d-10) nm. The sidewall angle is equal to θ.

Physical definitions are explained as follows.

The contrast refers to a ratio of a highest point and a lowest point of the photoresist after exposure and development. In the simulation, the image contrast is generally determined as a ratio of a difference between maximum and minimum light intensity on a photoresist layer to a sum of the maximum and minimum light intensity on the photoresist layer, and such image contrast is also called the Michelson contrast. Greater image contrast indicates that higher steepness of the pattern formed through photolithography, that is, better resolution of photolithography. Generally, the image contrast of a submicron pattern is required to be greater than 0.4 in case of a positive photoresist and greater than 0.2 in case of a negative photoresist. That is, there is a following equation when C represents the image contrast, Iₘₐₓ represents the maximum light intensity, and Iₘᵢₙ represents the minimum light intensity.

$$C = ( {I}_{max} - {I}_{min} ) / ( {I}_{max} + {I}_{min} )$$

FIG. 4 shows a graph of image contrasts of a pattern with respect to an incident angle of light from a light source for layers of absorption masks, which are made of Cr and OMOG (which is 10 nm Cr plus 50 nm MoSi), respectively, both of which have the thickness of 60 nm and the sidewall angle of 0°. The graph shows that the image contrast of the layer of Cr masks are higher than that of the layer of OMOG masks when the incident angle α ranges from 0° to 6°, and the contrast of the layer of the OMOG mask is higher than that of the layer of Cr masks when the incident angle α ranges from 6° to 18°. Thereby, selection can be made among different materials for the absorption masks under different processing parameters, so as to optimize the image contrast.

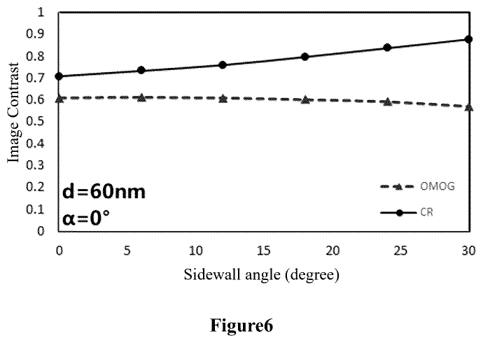

FIG. 5 shows a graph of image contrasts of a pattern with respect to a thickness for layers of absorption masks made of Cr and OMOG, respectively, both of which have a sidewall angle of 0° and are subject to vertical incident light. The thickness of Cr increases from 10 nm to 160 nm in case of the Cr masks. The thickness of Cr is constant while the thickness of MoSi increases from 0 nm to 150 nm in case of the OMOG masks. As shown in FIG. 5, the image contrast has different sensitivity and varies in different trends with respect to the thickness between the OMOG masks and the Cr masks. The graph shows that the image contrast for the layer of Cr masks is higher than that for the layer of OMOG masks within a thickness range from 0 nm to 80 nm under the vertical incident light. The image contrast for the layer of OMOG masks is higher than that for the layer of Cr masks within a thickness range from 80 nm to 160 nm. Thereby, selection can be made among different materials for the absorption masks under different thicknesses of the layer of the absorption masks, so as to optimize the image contrast.

FIG. 6 is a graph of image contrasts of a pattern with respect to a sidewall angle for layers of absorption masks made of Cr (d=60 nm) and OMOG (10 nm Cr plus 50 nm MoSi), respectively, both of which have a thickness of 60 nm and are subject to vertical incident light. The graph shows that the image contrasts of the two structures vary differently with an increase of the sidewall angle. The image contrast for the layer of Cr masks is more sensitive and increases gradually with respect to the increase of the sidewall angle. The image contrast for the layer of OMOG masks is subject to no significant improvement with respect to the increases of the sidewall angle.

The foregoing preferable embodiments of the present disclosure are only intended for helping illustrate the present disclosure, and the present disclosure is not limited thereto. Those skilled in the field can appreciate that technical solutions of the present disclosure may be modified, or some technical features may be combined in another manner, within the technical concept of the present disclosure. These modifications or combinations shall be construed as a part of the present disclosure and belong to the protection scope of the present disclosure, as long as their essence does not deviate from the spirit and scope of various technical solutions of the present disclosure.

1. A method for fabricating a multilayer superlens, comprising:
constructing a plurality of models for a structure of the multilayer superlens, wherein:
each model of the plurality of models comprises quartz glass, a layer of a plurality of absorption masks, a polymer spacer layer, and a multilayer structure comprising at least one metallic layer and at least one dielectric layer which are alternately stacked;
the layer of the plurality of absorption masks is disposed on a surface of the quartz glass;
the polymer spacer layer is disposed among the plurality of absorption masks and on a surface of the layer of the plurality of absorption masks;
the multilayer structure is disposed on a surface of the polymer spacer layer; and
all models in the plurality of models differ from each other in a parameter of the layer of the plurality of absorption masks;
simulating light transmission in each model of the plurality of model through software to obtain an image contrast of a pattern, which is formed at a central region of a photoresist coated on a base layer in photolithography using the multilayer superlens of the structure corresponding to said model;
determining the parameter of the layer of the plurality of absorption masks for the structure of the multilayer superlens based on the image contrast of each model; and
fabricating the multilayer superlens according to the determined parameter of the layer of the plurality of absorption masks.

2. The method according to claim 1, wherein the parameter of the layer of the plurality of absorption masks comprises at least one of:
a thickness of the layer of the plurality of absorption masks,
a type of a material of the layer of the plurality of absorption masks, or
an angle of a sidewall of each absorption mask in the plurality of absorption masks.

3. The method according to claim 2, wherein:
the thickness of the layer of the plurality of absorption masks ranges from 10 nm to 160 nm;
each absorption mask of the plurality of absorption masks comprises one or both of a MoSi layer and a Cr layer, wherein the MoSi layer is in contact with the quartz glass when said absorption mask comprises both the MoSi layer and the Cr layer; and
the angle of the sidewall of each absorption mask ranges 0° to 30°.

4. The method according to claim 2, wherein the plurality of models comprises:
first models, wherein the layer of the plurality of absorption masks of each of the first structures comprises a Cr layer, and the first structures differ from each other in a thickness of the Cr layer; and
second models, wherein the layer of the plurality of absorption masks of each of the second structures comprises a MoSi layer and a Cr layer, the second structures differ from each other in a thickness of the MoSi layer and are identical in the thickness of the Cr layer, and the MoSi layer is in contact with the quartz glass.

5. The method according to claim 2, wherein the plurality of structures comprises:
third models, which differ from each other in the angle of the sidewall of each absorption mask.

6. The method according to claim 1, wherein:
a width of a gap between adjacent absorption masks in the plurality of absorption masks ranges from 140 nm to 160 nm, and
a periodical dimension of the plurality of absorption masks ranges from 280 nm to 320 nm.

7. The method according to claim 1, wherein a thickness of the polymer spacer layer ranges from 100 nm to 200 nm, and a thickness of the multilayer structure ranges from 250 nm to 350 nm.

8. The method according to claim 1, wherein:
the polymer spacer layer comprises a polymethyl-methacrylate (PMMA) layer;
the multilayer structure comprises at least one silver layer and at least one titanium dioxide layer which are alternately stacked, and one of the at least one titanium dioxide layer is a layer closest to the polymer spacer layer in the multilayer structure.

9. The method according to claim 1, wherein simulating the light transmission in each structure of the plurality of structures through the software modelling comprises:
altering an incident angle of light from a light source to obtain the image contrast, wherein the incident angle ranges from 0° to 20°.

10. A plasmonic superlens, fabricated through:
constructing a plurality of models for a structure of the multilayer superlens, wherein:
each model of the plurality of models comprises quartz glass, a layer of a plurality of absorption masks, a polymer spacer layer, and a multilayer structure comprising at least one metallic layer and at least one dielectric layer which are alternately stacked;
the layer of the plurality of absorption masks is disposed on a surface of the quartz glass;
the polymer spacer layer is disposed among the plurality of absorption masks and on a surface of the layer of the plurality of absorption masks;
the multilayer structure is disposed on a surface of the polymer spacer layer; and
all models in the plurality of models differ from each other in a parameter of the layer of the plurality of absorption masks;
simulating light transmission in each model of the plurality of model through software to obtain an image contrast of a pattern, which is formed at a central region of a photoresist coated on a base layer in photolithography using the multilayer superlens of the structure corresponding to said model;
determining the parameter of the layer of the plurality of absorption masks for the structure of the multilayer superlens based on the image contrast of each model; and
fabricating the multilayer superlens according to the determined parameter of the layer of the plurality of absorption masks.
